(19) United States
(12) Patent Application Publication
(10) Pub. No.: US 2019/0057917 A1
(43) Pub. Date: Feb. 21, 2019

(54) ELECTRONIC PACKAGE AND METHOD OF FABRICATING THE SAME

(71) Applicant: Siliconware Precision Industries Co., Ltd., Taichung (TW)

(72) Inventors: Wen-Shan Tsai, Taichung City (TW); Chee-Key Chung, Taichung City (TW); Chang-Fu Lin, Taichung City (TW)

(21) Appl. No.: 15/860,222

(22) Filed: Jan. 2, 2018

(30) Foreign Application Priority Data
Aug. 16, 2017 (TW) 106127763

(51) Int. Cl. H01L 23/31; H01L 23/498; H01L 23/29; H01L 23/00; H01L 21/56; H01L 21/48

(52) U.S. Cl. CPC H01L 23/3114; H01L 2924/0665; H01L 23/3128; H01L 23/49816; H01L 23/295; H01L 23/49894; H01L 24/81; H01L 21/565; H01L 21/4853; H01L 21/561; H01L 24/16; H01L 24/97; H01L 23/49827; H01L 2224/16225; H01L 2924/3511; H01L 23/49838

(57) ABSTRACT

An electronic package and a method of fabricating the same are provided. The method includes disposing an electronic component on a first side of an interposer, forming a first encapsulant on the first side of the interposer to encapsulate the electronic component, forming a plurality of conductive elements on a second side of the interposer, and forming a second encapsulant on the second side of the interposer to encapsulate the conductive elements. During thermal cycling of the electronic package, shrinkage forces of the first encapsulant and the second encapsulant can offset each other so as to mitigate warping of the interposer.

### BACKGROUND

### 1. Technical Field

The present disclosure relates to semiconductor package structures, and, more particularly, to an electronic package and a method of fabricating the same capable of mitigating structural warping.

### 2. Description of Related Art

Along with the rapid development of electronic industries, electronic products are developed toward the trend of multi-function and high performance. Accordingly, various types of flip-chip packaging modules, such as chip scale packages (CSPs), direct chip attached (DCA) packages and multi-chip modules (MCM) and 3D IC chip stacking technologies, have been developed so as to reduce chip packaging sizes and shorten signal transmission paths.

FIGS. 1A and 1B are schematic cross-sectional views showing a method for fabricating a 3D IC chip staking-type package structure 1 according to the prior art. Referring to FIG. 1A, a silicon interposer 10 is provided. The silicon interposer 10 has a chip mounting side 10a, an external connection side 10b opposite to the chip mounting side 10a and having an RDL (redistribution layer) structure 101 formed thereon, and a plurality of through silicon vias (TSVs) 100 communicating with the chip mounting side 10a and the external connection side 10b. A plurality of electrode pads 190 of a semiconductor chip 19 are bonded and electrically connected to the chip mounting side 10a of the silicon interposer 10 through a plurality of solder bumps 102. Further, an underfill 192 is formed between the semiconductor chip 19 and the chip mounting side 10a of the silicon interposer 10 for encapsulating the solder bumps 102. Furthermore, an encapsulant 18 is formed on the silicon interposer 10 to encapsulate the semiconductor chip 19. Then, referring to FIG. 1B, the RDL structure 101 is bonded and electrically connected to a plurality of bonding pads 170 of a packaging substrate 17 through a plurality of conductive elements 103, such as solder bumps, and another underfill 172 is formed to encapsulate the conductive elements 103.

However, referring to FIG. 1A, since the encapsulant 18 is only formed on the chip mounting side 10a of the silicon interposer 10, a shrinkage force generated by the encapsulant 18 during thermal cycling may cause serious warping of the structure of FIG. 1A. Consequently, during the process of FIG. 1B, the conductive elements 103 cannot be accurately aligned to the bonding pads 170 of the packaging substrate 17, thus adversely affecting the electrical connection quality.

Therefore, how to overcome the above-described drawbacks has become critical.

### SUMMARY

In view of the above-described drawbacks, the present disclosure provides an electronic package, which comprises: an interposer having a first side and a second side opposite to the first side; an electronic component disposed on the first side of the interposer; a first encapsulant formed on the first side of the interposer to encapsulate the electronic component; a plurality of conductive elements formed on the second side of the interposer; and a second encapsulant formed on the second side of the interposer to encapsulate the conductive elements, wherein portions of surfaces of the conductive elements are exposed from the second encapsulant.

The present disclosure further provides a method for fabricating an electronic package, which comprises: providing an interposer having a first side and a second side opposite to the first side; disposing an electronic component on the first side of the interposer; forming a first encapsulant on the first side of the interposer to encapsulate the electronic component; forming a plurality of conductive elements on the second side of the interposer; and forming a second encapsulant on the second side of the interposer to encapsulate the conductive elements, wherein portions of surfaces of the conductive elements are exposed from the second encapsulant.

In an embodiment, the first encapsulant and the second encapsulant may be made of an epoxy resin comprising a resin component and a filler component. In another embodiment, the resin component of the first encapsulant has a different weight percentage than the resin component of the second encapsulant. In yet another embodiment, the resin component of the second encapsulant has a greater weight percentage than the resin component of the first encapsulant. In still another embodiment, the filler component of the first encapsulant has a different weight percentage from the filler component of the second encapsulant. In yet still another embodiment, the filler component of the first encapsulant has a greater weight percentage than the filler component of the second encapsulant.

In an embodiment, the first encapsulant may be greater in volume than the second encapsulant. In an embodiment, the first encapsulant is equal in width to the second encapsulant. In an embodiment, the first encapsulant is greater in thickness than the second encapsulant. In an embodiment, the first encapsulant is at least 1.3 times greater in thickness than the second encapsulant.

In an embodiment, the first encapsulant may be equal in width to the interposer.

In an embodiment, the second encapsulant may be equal in width to the interposer.

In an embodiment, the conductive elements may protrude from the second encapsulant.

In an embodiment, the thickness of the second encapsulant may be less than a half of a thickness of at least one of the conductive elements.

According to the present disclosure, the first encapsulant and the second encapsulant are formed on the first side and the second side of the interposer, respectively, such that shrinkage forces of the first encapsulant and the second encapsulant during thermal cycling can offset one another, thereby providing balanced stresses on the interposer and mitigating warping of the interposer. Hence, in a subsequent process, the conductive elements can be accurately aligned and bonded to electrical contacts of a packaging substrate so as to improve the electrical connection quality.

### BRIEF DESCRIPTION OF DRAWINGS

FIGS. 1A and 1B are schematic cross-sectional views showing a method for fabricating a package structure according to the prior art;

FIGS. 2A to 2E are schematic cross-sectional views showing a method for fabricating an electronic package according to the present disclosure; and

FIG. 3 is a schematic cross-sectional view showing a subsequent process of FIG. 2E.

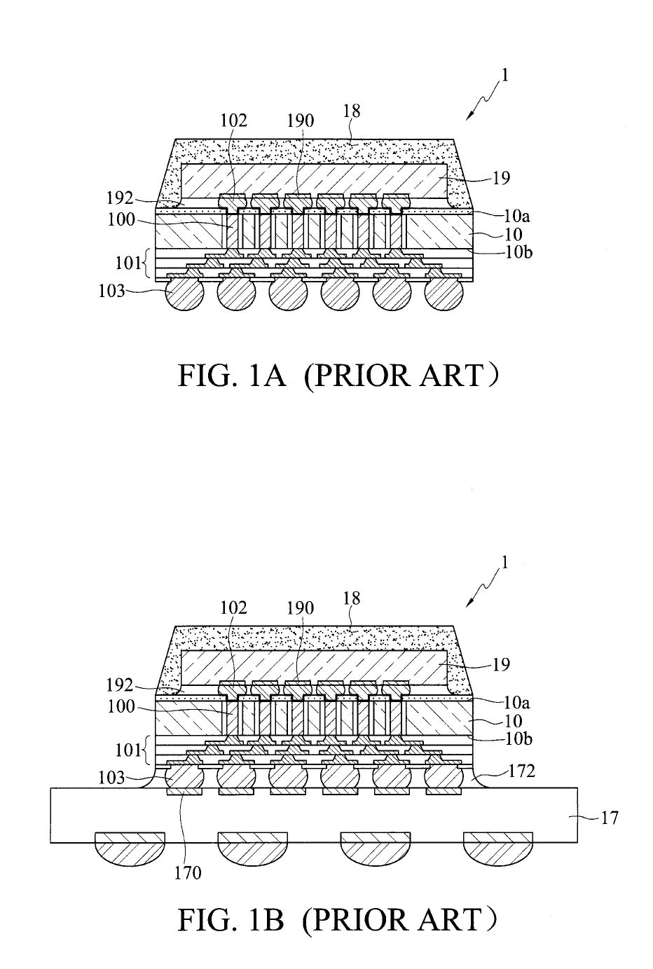

### DETAILED DESCRIPTION OF PREFERRED EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

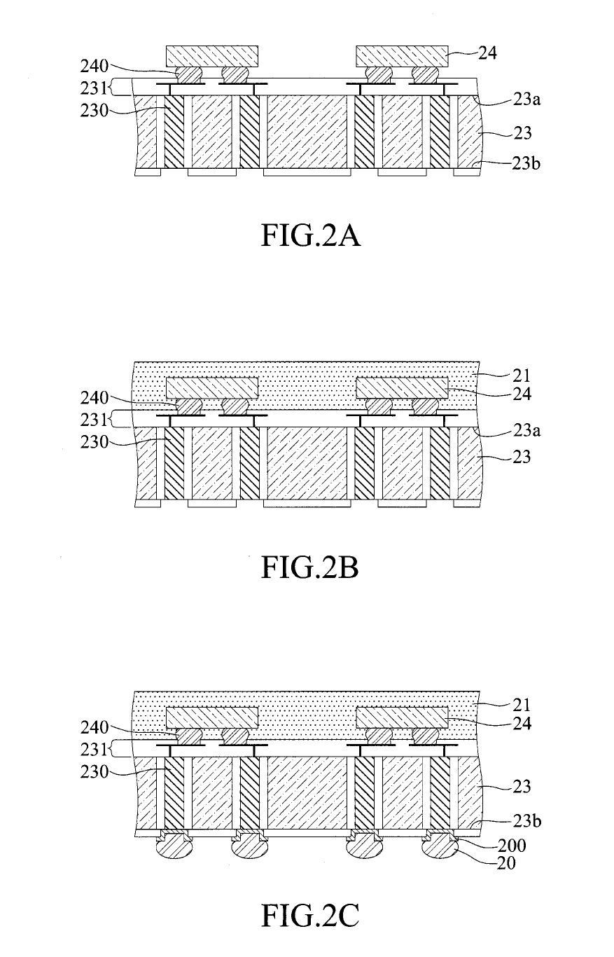

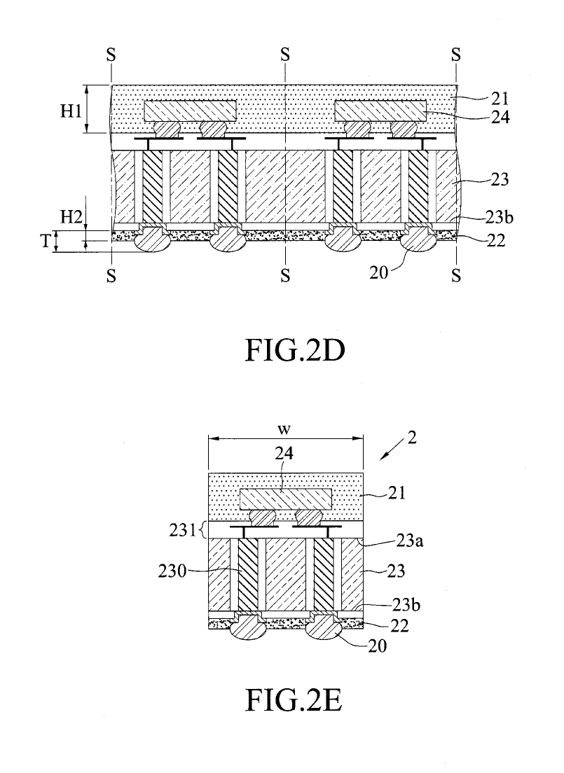

FIGS. 2A to 2E are schematic cross-sectional views showing a method for fabricating an electronic package 2 according to the present disclosure.

Referring to FIG. 2A, an interposer 23 having a first side 23a and a second side 23b opposite to the first side 23a is provided, and a plurality of electronic components 24 are disposed on the first side 23a of the interposer 23.

In an embodiment, the interposer 23 is a semiconductor substrate, such as a silicon substrate or a glass substrate, which has a plurality of conductive through holes 230 communicating with the first side 23a and the second side 23b, and at least one redistribution layer 231 formed on the first side 23a and electrically connected to the conductive through holes 230. In another embodiment, the redistribution layer 231 can be formed on the second side 23b of the interposer 23 and electrically connected to the conductive through holes 230. In yet another embodiment, the redistribution layer 231 is formed on both the first side 23a and the second side 23b of the interposer 23 and electrically connected to the conductive through holes 230.

Each of the electronic components 24 is an active element, such as a semiconductor chip, a passive element, such as a resistor, a capacitor or an inductor, or a combination thereof. In an embodiment, the electronic component 24 is a semiconductor chip, which is electrically connected to the redistribution layer 231 through a plurality of solder bumps 240. In another embodiment, the electronic component 24 is electrically connected to the redistribution layer 231 through a plurality of bonding wires (not shown). In further another embodiment, the electronic component 24 is in direct contact with the redistribution layer 231.

Referring to FIG. 2B, a first encapsulant 21 is formed on the first side 23a of the interposer 23 to encapsulate the electronic components 24.

In an embodiment, the first encapsulant 21 is made of polyimide, a dry film, an epoxy resin or a molding compound.

Referring to FIG. 2C, a plurality of conductive elements 20 are formed on the second side 23b of the interposer 23 and electrically connected to the conductive through holes 230.

In an embodiment, a UBM (under bump metallurgy) layer 200 can be formed between the conductive through holes 230 and the conductive elements 20 according to the practical need. In another embodiment, the conductive elements 20 are formed on end surfaces of the conductive through holes 230, and the conductive elements 20 are, for example, solder balls, or other metal bumps, such as copper posts.

Referring to FIG. 2D, a second encapsulant 22 is formed on the second side 23b of the interposer 23 to encapsulate the conductive elements 20. In an embodiment, portions of surfaces of the conductive elements 20 are exposed from the second encapsulant 22.

In an embodiment, the second encapsulant 22 is made of polyimide, a dry film, an epoxy resin or a molding compound. The second encapsulant 22 and the first encapsulant 21 can be made of the same or different material.

Further, the first encapsulant 21 and the second encapsulant 22 are made of an epoxy resin including a resin component and a filler component. The resin component of the first encapsulant 21 is different from the resin component of the second encapsulant 22. In an embodiment, the resin component of the second encapsulant 22 has a greater weight percentage than the resin component of the first encapsulant 21. As such, the second encapsulant 22 generates a shrinkage force that is greater than and opposite in direction to the shrinkage force generated by the first encapsulant 21, thus reducing occurrence of warping of the interposer 23. In an embodiment, the resin component of the first encapsulant 21 is less than 20 wt %, and the resin component of the second encapsulant 22 is greater than or equal to 20 wt %. In other words, the filler component of the first encapsulant 21 is different from the filler component of the second encapsulant 22. In an embodiment, the filler component of the first encapsulant 21 is greater than or equal to 80 wt %, and the filler component of the second encapsulant 22 is less than 80 wt %.

Furthermore, the first encapsulant 21 is greater in volume than the second encapsulant 22. For example, if the first encapsulant 21 is equal in width to the second encapsulant 22 (or both are equal in width to the interposer 23), the thickness H1 of the first encapsulant 21 is greater than the thickness H2 of the second encapsulant 22. Preferably, the ratio of the thickness H1 of the first encapsulant 21 and the thickness H2 of the second encapsulant 22 is greater than or equal to 1.3 so as to achieve a preferred warping control.

In an embodiment, portions of the surfaces, such as end surfaces, of the conductive elements 20, protrude from the second encapsulant 22 so as to be exposed from the second encapsulant 22. In an embodiment, the thickness H2 of the second encapsulant 22 is less than a half the thickness T of the conductive elements 20. That is, H2<T/2. In other embodiments, the end surfaces of the conductive elements 20 are flush with a lower surface of the second encapsulant 22 so as to be exposed from the second encapsulant 22, or a plurality of openings are formed in the second encapsulant 22 to expose the conductive elements 20.

Referring to FIG. 2E, a singulation process is performed along cutting paths S of FIG. 2D to obtain a plurality of electronic packages 2.

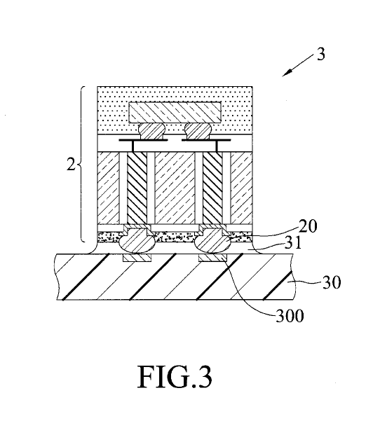

In a subsequent process, referring to FIG. 3, the electronic package 2 is bonded to an electronic device 30, such as a packaging substrate, through the conductive elements 20 and then an underfill 31 is formed to encapsulate the conductive elements 20, thus forming a package structure 3. In particular, the electronic device 30 has a plurality of electrical contacts 300 bonded to the conductive elements 20.

According to the present disclosure, the first encapsulant 21 and the second encapsulant 22 are formed on the first side 23a and the second side 23b of the interposer 23, respectively, such that shrinkage forces of the first encapsulant 21 and the second encapsulant 22 during thermal cycling can offset one another, thus providing balanced stresses on the two opposite sides 23a and 23b of the interposer 23 and mitigating warping of the interposer 23. Hence, in a subsequent process, the conductive elements 20 can be accurately aligned and bonded to the electrical contacts 300 of the packaging substrate 30 so as to improve the electrical connection quality.

The present disclosure further provides an electronic package 2, which has: an interposer 23 having a first side 23a and a second side 23b opposite to the first side 23a; an electronic component 24 disposed on the first side 23a of the interposer 23; a first encapsulant 21 formed on the first side 23a of the interposer 23 to encapsulate the electronic component 24; a plurality of conductive elements 20 formed on the second side 23b of the interposer 23; and a second encapsulant 22 formed on the second side 23b of the interposer 23 to encapsulate the conductive elements 20, wherein portions of surfaces of the conductive elements 20 are exposed from the second encapsulant 22.

In an embodiment, the first encapsulant 21 and the second encapsulant 22 are made of an epoxy resin comprising a resin component and a filler component, and the resin component of the first encapsulant 21 is different form the resin component of the second encapsulant 22. In an embodiment, the resin component of the second encapsulant 22 has a greater weight percentage than the resin component of the first encapsulant 21. In another embodiment, the filler component of the first encapsulant 21 is different from the filler component of the second encapsulant 22. In yet another embodiment, the filler component of the first encapsulant 21 has a greater weight percentage than the filler component of the second encapsulant 22.

In an embodiment, the first encapsulant 21 is greater in volume than the second encapsulant 22. In an embodiment, the width W of the first encapsulant 21 is equal to the width W of the second encapsulant 22, and the thickness H1 of the first encapsulant 21 is greater than the thickness H2 of the second encapsulant 22. In another embodiment, the ratio of the thickness H1 of the first encapsulant 21 and the thickness H2 of the second encapsulant 22 is greater than or equal to 1.3.

In an embodiment, the width W of the first encapsulant 21 is equal to the width W of the interposer 23.

In an embodiment, the width W of the second encapsulant 22 is equal to the width W of the interposer 23.

In an embodiment, the conductive elements 20 protrude from the second encapsulant 22.

In an embodiment, the thickness H2 of the second encapsulant 22 is less than a half of the thickness T of the conductive elements 20.

According to the present disclosure, the first encapsulant and the second encapsulant are formed on the first side and the second side of the interposer, respectively, such that shrinkage forces of the first encapsulant and the second encapsulant during thermal cycling can offset one another, thus providing balanced stresses on the interposer and mitigating warping of the interposer. Hence, in a subsequent process, the conductive elements can be accurately aligned and bonded to electrical contacts of a packaging substrate so as to improve the electrical connection quality.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. An electronic package, comprising:
an interposer having a first side and a second side opposite to the first side;
an electronic component disposed on the first side of the interposer;
a first encapsulant formed on the first side of the interposer and encapsulating the electronic component;
a plurality of conductive elements disposed on the second side of the interposer; and
a second encapsulant formed on the second side of the interposer and encapsulating the conductive elements, wherein portions of surfaces of the conductive elements are exposed from the second encapsulant.

2. The electronic package of claim 1, wherein the first encapsulant and the second encapsulant are made of an epoxy resin comprising a resin component and a filler component, and the resin component of the first encapsulant has a different weight percentage from the resin component of the second encapsulant.

3. The electronic package of claim 2, wherein the resin component of the second encapsulant has a greater weight percentage than the resin component of the first encapsulant.

4. The electronic package of claim 2, wherein the filler component of the first encapsulant has a different weight percentage from the filler component of the second encapsulant.

5. The electronic package of claim 4, wherein the filler component of the first encapsulant has a greater weight percentage than the filler component of the second encapsulant.

6. The electronic package of claim 1, wherein the first encapsulant is greater in volume than the second encapsulant.

7. The electronic package of claim 6, wherein the first encapsulant is equal in width to at least one of the second encapsulant and the interposer, or the first encapsulant is greater in thickness than the second encapsulant.

8. The electronic package of claim 6, wherein a ratio of a thickness of the first encapsulant and a thickness of the second encapsulant is greater than or equal to 1.3.

9. The electronic package of claim 1, wherein the second encapsulant is equal in width to the interposer, or the second encapsulant has a thickness less than a half of a thickness of at least one of the conductive elements.

10. The electronic package of claim 1, wherein the conductive elements protrude from the second encapsulant.

11. A method for fabricating an electronic package, comprising:
providing an interposer having a first side and a second side opposite to the first side;
disposing an electronic component on the first side of the interposer;
forming on the first side of the interposer a first encapsulant encapsulating the electronic component;
forming a plurality of conductive elements on the second side of the interposer; and
forming on the second side of the interposer a second encapsulant encapsulating the conductive elements, wherein portions of surfaces of the conductive elements are exposed from the second encapsulant.

12. The method of claim 11, wherein the first encapsulant and the second encapsulant are made of an epoxy resin comprising a resin component and a filler component, and the resin component of the first encapsulant has a different weight percentage from the resin component of the second encapsulant.

13. The method of claim 12, wherein the resin component of the second encapsulant has a greater weight percentage than the resin component of the first encapsulant.

14. The method of claim 12, wherein the filler component of the first encapsulant has a different weight percentage from the filler component of the second encapsulant.

15. The method of claim 14, wherein the filler component of the first encapsulant has a greater weight percentage than the filler component of the second encapsulant.

16. The method of claim 11, wherein the first encapsulant is greater in volume than the second encapsulant.

17. The method of claim 16, wherein the first encapsulant is equal in width to at least one of the second encapsulant and the interposer, or the first encapsulant is greater in thickness than the second encapsulant.

18. The method of claim 16, wherein a ratio of a thickness of the first encapsulant and a thickness of the second encapsulant is greater than or equal to 1.3.

19. The method of claim 11, wherein the second encapsulant is equal in width to the interposer, or the second encapsulant has a thickness less than a half of a thickness of at least one of the conductive elements.

20. The method of claim 11, wherein the conductive elements protrude from the second encapsulant.
